(19) United States
(12) Patent Application Publication
(10) Pub. No.: US 2018/0061679 A1
(43) Pub. Date: Mar. 1, 2018

(54) MULTI CHAMBER PROCESSING SYSTEM WITH SHARED VACUUM SYSTEM

(71) Applicant: APPLIED MATERIALS, INC., Santa Clara, CA (US)

(72) Inventors: Fernando M. SILVEIRA, Livermore, CA (US); Chunlei ZHANG, Saratoga, CA (US); David ULLSTROM, San Jose, CA (US); Michael R. RICE, Pleasanton, CA (US)

(21) Appl. No.: 15/683,967

(22) Filed: Aug. 23, 2017

Related U.S. Application Data
(60) Provisional application No. 62/379,698, filed on Aug. 25, 2016.

(51) Int. Cl. H01L 21/67; H01J 37/32

(52) U.S. Cl. CPC H01L 21/67063; H01J 37/32899

(57) ABSTRACT

Methods and apparatus for a multi-chamber processing system having shared vacuum systems are disclosed herein. In some embodiments, a multi-chamber processing system for processing substrates includes a first process chamber; a second process chamber; a first vacuum system coupled to the first and second process chambers through first and second valves and to a first shared vacuum pump; and a second vacuum system coupled to the first and second process chambers through third and fourth valves and to a second shared vacuum pump, wherein the second vacuum system is fluidly independent from the first vacuum system.

### CROSS-REFERENCE TO RELATED APPLICATIONS

This application claims the benefit of U.S. Provisional Patent Application No. 62/379,698, filed with the United States Patent Office on Aug. 25, 2016, which is herein incorporated by reference in its entirety.

### FIELD

Embodiments of the present disclosure generally relate to substrate processing systems, and more specifically to methods and apparatus for multi-chamber processing systems.

### BACKGROUND

Processing systems, for example, such as cluster tool having multiple process chambers on a shared transfer chamber are utilized to reduce system and manufacturing costs and improve process throughput. However, conventional process chambers are independently configured with the process resources necessary to facilitate performing the particular process therein. Such systems are costly to own and operate.

Therefore, systems have been developed where system costs can be further reduced by sharing resources between process chambers. Specifically, processing systems may have shared resources such as, for example, a shared vacuum pump, a shared gas panel, or the like to reduce system and substrate manufacturing costs. Unfortunately, as a result of sharing a vacuum pump, the inventors have further discovered that servicing of a first process chamber of the multi-chamber processing system requires shutting down at least one other process chamber of the multi-chamber processing system, thus decreasing the throughput of the system.

Accordingly, the inventors provide an improved multi-chamber processing system having a shared vacuum system.

### SUMMARY

Methods and apparatus for a multi-chamber processing system having shared vacuum systems are disclosed herein. In some embodiments, a multi-chamber processing system for processing substrates includes a first process chamber; a second process chamber; a first vacuum system coupled to the first and second process chambers through first and second valves and to a first shared vacuum pump; and a second vacuum system coupled to the first and second process chambers through third and fourth valves and to a second shared vacuum pump, wherein the second vacuum system is fluidly independent from the first vacuum system.

In some embodiments, a method of a method of selectively coupling a chamber of a multi-chamber processing system to one of a first vacuum system or a second vacuum system includes closing a first valve coupling the chamber to the first vacuum system to isolate the chamber from the first vacuum system; performing servicing of the chamber; opening a third valve coupling the chamber to the second vacuum system; pumping down the chamber to a crossover pressure using a second shared vacuum pump coupled to the second vacuum system; closing the third valve to isolate the chamber from the second vacuum system; and opening the first valve to fluidly couple the chamber to the first vacuum system to allow the chamber to resume operation, wherein the first and second vacuum systems are fluidly independent of each other and are coupled to all chambers of the multi-chamber processing system.

In some embodiments, a multi-chamber processing system for processing substrates includes a first process chamber having a first process volume; a second process chamber having a second process volume; a first vacuum system coupled to the first and second process chambers through first and second valves and to a roughing pump; and a second vacuum system coupled to the first and second process chambers through third and fourth valves and to a turbomolecular pump, wherein the second vacuum system is fluidly independent from the first vacuum system, wherein the roughing pump is configured to maintain a processing pressure in all chambers of the multi-chamber processing system, and wherein the turbomolecular pump is configured to reduce a pressure in one of the first and second processing volumes being serviced below a crossover pressure less than the processing pressure provided by the roughing pump.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of the scope of the disclosure, for the disclosure may admit to other equally effective embodiments.

FIG. 1 depicts a schematic top view of a processing system in accordance with some embodiments of the present disclosure.

FIG. 2 depicts a schematic side view of a multi-chamber processing system in accordance with some embodiments of the present disclosure.

FIG. 3 depicts a flow chart for a method of servicing one chamber of a multi-chamber processing system in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatus for a multi-chamber processing system having a shared vacuum system are disclosed herein. The inventive multi-chamber processing system includes a shared vacuum system that advantageously allows one chamber to be serviced while allowing a process to run in the other chambers uninterrupted. Further, the inventive methods advantageously control operation of shared vacuum system to facilitate the servicing of one chamber while allowing processes in the other chambers of the multi-chamber processing system to continue uninterrupted.

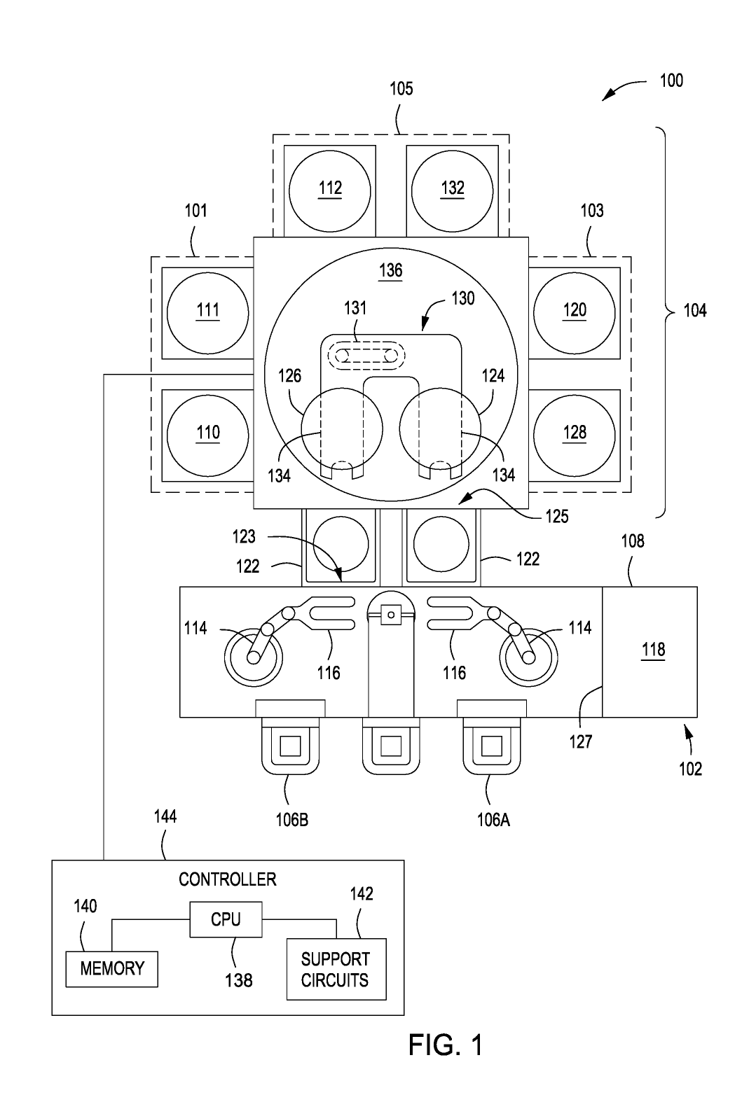

A multi-chamber processing system disclosed herein may be part of a cluster tool having several twin chamber processing systems coupled thereto, for example, such as a processing system 100 illustrated in FIG. 1. Referring to FIG. 1, in some embodiments, the processing system 100 may generally comprise a vacuum-tight processing platform 104, a factory interface 102, one or more twin chamber processing systems 101, 103, 105 and a system controller 144. Examples of processing systems that may be suitably modified in accordance with the teachings provided herein include the CENTURA® integrated processing system, one of the PRODUCER® line of processing systems (such as the PRODUCER® GTT™), ADVANTEDGE™ processing systems, CENTRIS® processing systems, or other suitable processing systems commercially available from Applied Materials, Inc., located in Santa Clara, Calif. Other processing systems (including those from other manufacturers) may be adapted to benefit from the disclosure.

The processing platform 104 includes one or more twin chamber processing systems 101, 103, 105 (three shown in FIG. 1), wherein each twin chamber processing system includes two process chambers (e.g., 110 and 111, 112 and 132, and 120 and 128). The platform further includes at least one load-lock chamber 122 (two shown in FIG. 1) that are coupled to a substrate transfer chamber 136 at vacuum. The factory interface 102 is coupled to the transfer chamber 136 via the load lock chambers 122.

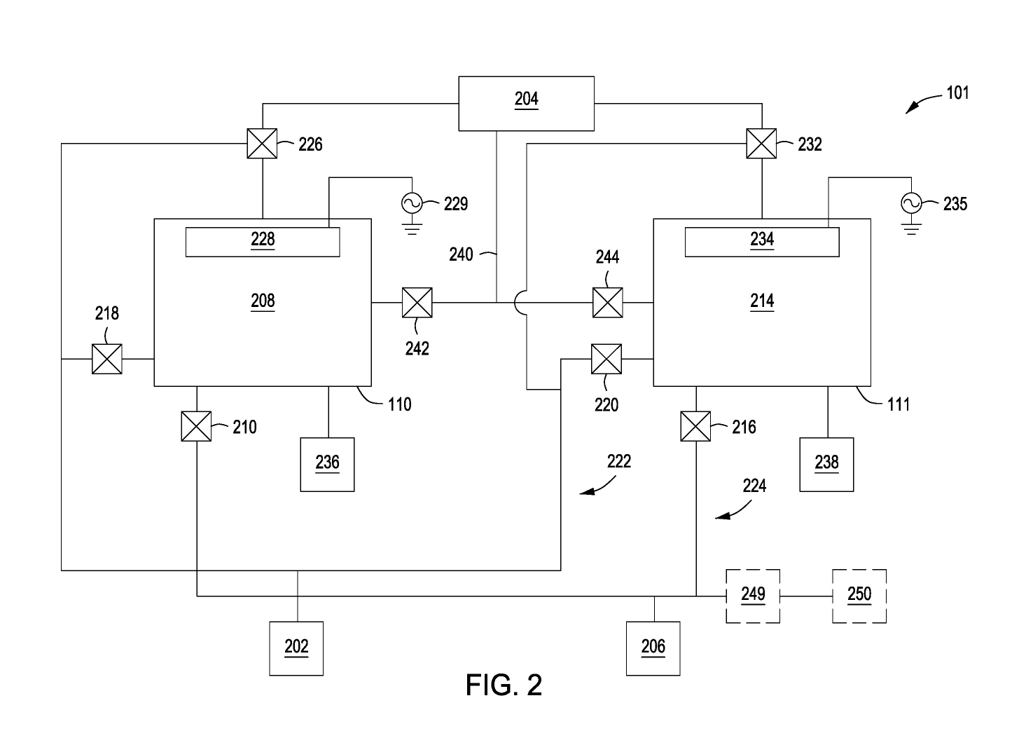

Each twin chamber processing system 101, 103, 105 includes independent processing volumes that may be isolated from each other. Each twin chamber processing system 101, 103, 105 may be configured to share resources (e.g., process gas supply, vacuum pump, or the like) between each process chamber of the twin chamber processing system as discussed below and illustrated in FIG. 2.

The factory interface 102 may comprise at least one docking station 108 and at least one factory interface robot 114 (two shown in FIG. 1) to facilitate transfer of substrates. The docking station 108 may be configured to accept one or more (two shown in FIG. 1) front opening unified pods (FOUPs) 106A-B. The factory interface robot 114 may comprise a blade 116 disposed on one end of the factory interface robot 114 configured to transfer the substrate from the factory interface 102 to the processing platform 104 for processing through the load lock chambers 122. Optionally, one or more metrology stations 118 may be connected to a terminal 127 of the factory interface 102 to facilitate measurement of the substrate from the FOUPs 106A-B.

Each of the load lock chambers 122 may include a first port 123 coupled to the factory interface 102 and a second port 125 coupled to the transfer chamber 136. The load lock chambers 122 may be coupled to a pressure control system (not shown) which pumps down and vents the load lock chambers 122 to facilitate passing the substrate between the vacuum environment of the transfer chamber 136 and the substantially ambient (e.g., atmospheric) environment of the factory interface 102.

The transfer chamber 136 has a vacuum robot 130 disposed therein. The vacuum robot 130 may have one or more transfer blades 134 (two shown in FIG. 1) coupled to a movable arm 131. For example, in some embodiments, where twin chamber processing systems are coupled to the transfer chamber 136 as shown, the vacuum robot 130 may have two parallel transfer blades 134 configured such that the vacuum robot 130 may simultaneously transfer two substrates 124, 126 between the load lock chambers 122 and the process chambers of a twin chamber processing system, for example, process chambers 110, 111 of the twin chamber processing system 101.

The process chambers 110, 111 or 112, 132 or 120, 128 of each twin chamber processing system 101, 103, 105 may be any type of process chamber utilized in substrate processing, for example, such as etch chambers, deposition chambers, or the like. In some embodiments, the process chambers, for example process chambers 110, 111, of each twin chamber processing system, for example twin chamber processing system 101 are configured for the same function, for example, etching. For example, in embodiments where each process chamber of a twin chamber processing system is an etch chamber, each process chamber may include a plasma source, for example, an inductive or capacitively coupled plasma source, a remote plasma source or the like. Further, each process chamber of a twin chamber processing system may use a halogen-containing gas, for example, provided by a shared gas panel (as discussed below), to etch substrates (e.g., substrates 124, 126) disposed therein. Examples of halogen-containing gas include hydrogen bromide (HBr), chlorine (Cl₂), carbon tetrafluoride (CF₄), and the like. For example, after etching the substrates 124, 126, halogen-containing residues may remain on the substrate surface. The halogen-containing residues may be removed by a thermal treatment process in the load lock chambers 122, or by other suitable means.

FIG. 2 depicts a schematic side view of a twin chamber processing system, for example twin chamber processing system 101, in accordance with some embodiments of the present disclosure. The twin chamber processing system 101 includes the process chambers 110, 111, wherein the process chambers 110, 111 share resources, for example, such as a first vacuum system 222, a second vacuum system 224 fluidly independent from the first vacuum system 222, and a shared gas panel 204 as shown in FIG. 2. The first vacuum system 222 includes a first shared vacuum pump 202. The second vacuum system 224 includes a second shared vacuum pump 206.

In some embodiments, each twin chamber processing system coupled to the processing system 100 may be similarly configured. The process chamber 110 (e.g., a first process chamber) has a first processing volume 208 that includes a first substrate support disposed therein to support a first substrate (not shown). The process chamber 111 (e.g., a second process chamber) of the twin chamber processing system 101 includes a second processing volume 214 having a second substrate support disposed therein to support a second substrate.

The first and second processing volumes 208, 214 may be isolated from each other to facilitate substantially independent processing of substrates in each respective process chamber 110, 111. The isolated processing volumes of the process chambers within the twin chamber processing system advantageously reduces or eliminates processing problems that may arise due to multi-substrate processing systems where the processing volumes are fluidly coupled during processing. However, the twin chamber processing system further advantageously utilizes shared resources that facilitate reduced system footprint, hardware expense, utilities usage and cost, maintenance, and the like, while at the same time promoting higher substrate throughput. For example, shared hardware may include one or more of a process foreline and roughing pump, AC distribution and DC power supplies, cooling water distribution, chillers, multi-channel thermo controllers, gas panels, controllers, and the like.

Existing multi-chamber systems include two or more chambers coupled to a first pump for maintaining a processing pressure in the chambers during processing and a second pump for pumping down the process chambers to an operating pressure of the first pump after the chambers are serviced. However, because the chambers are coupled to the first and second pumps via common plumbing, when a first chamber is deactivated for servicing, the other process chamber(s), which is not being serviced, must also be deactivated. The other chamber(s) is deactivated because any particles or contaminants generated during servicing, which is usually performed at atmospheric pressure, may travel from the first chamber to the other chamber(s) (i.e., higher pressure chamber to lower pressure chamber) when both chambers are fluidly coupled to the second pump again. As such, the inventors have developed a shared vacuum system that includes a first vacuum system 222 and a second vacuum system 224 that are fluidly independent from each other.

The first shared vacuum pump 202 is coupled to the first and second processing volumes 208, 214 through first and second valves 218, 220, respectively. Similarly, the second shared vacuum pump 206 is coupled to the first and second processing volumes 208, 214 through third and fourth valves 210, 216, respectively. For example, the second shared vacuum pump 206 may be coupled to the first and second processing volumes 208, 214 for reducing a pressure in one of the first and second processing volumes 208,214 being serviced below a crossover pressure level (e.g., less than about 200 mTorr) prior to opening one of the first and second valves 218, 220 to fluidly couple the first shared vacuum pump 202 to the process volume that was serviced. For example, the crossover pressure level may be a lower pressure than an operating pressure provided by the first shared vacuum pump 202 during processing. However, the crossover pressure level may be a pressure required for the first shared vacuum pump 202 to begin operation.

During processing, the third and fourth valves 210,216 are in the closed position and the first and second valves 218,220 are in the open position to fluidly couple the first and second processing volumes 208, 214 only to the first shared vacuum pump 202 to maintain a processing pressure in the processing volumes. When, for example, the first process chamber 110 needs to be serviced, the first valve 218 is closed, thus isolating the first process chamber 110 from the first vacuum system 222 while the second process chamber 111 is allowed to continue operation. After servicing of the first process chamber 110 is completed, the third valve 210 is opened to fluidly couple the first process volume 208 to the second shared vacuum pump 206 to pump the first process volume 208 down to a crossover pressure (e.g., less than about 200 mTorr). Because the fourth valve 216 is closed and the second vacuum system 224 is fluidly independent from the first vacuum system 222, particles or contaminants created during the servicing of the first process chamber 110 are advantageously prevented from traveling to the second process chamber 111 due to the second process chamber 111 being at a lower pressure than the first process chamber 110. After the first processing volume 208 reaches the crossover pressure, the third valve 210 is closed and the first valve 218 is opened to fluidly couple the first process volume 208 to the first vacuum system 222 to allow the first process chamber 110 to continue operation.

The first shared vacuum pump 202 is capable of maintaining a processing pressure in all the chambers to which the second shared vacuum pump 206 is coupled during processing. In some embodiments, for example, the first shared vacuum pump 202 is a roughing pump large enough to maintain a processing pressure in the first and second process chambers 110, 111 during processing. In some embodiments, the second shared vacuum pump 206 may be a turbomolecular pump. Although the first and second vacuum systems 222, 224 are described above and illustrated in FIG. 2 as coupled to two process chambers, the first and second vacuum systems 222, 224 may alternatively be coupled to all of the process chambers 110, 111, 112, 132, 120, 128 of the processing system 100 depicted in FIG. 1. In some embodiments, instead of separate valves coupling each process chamber to respective ones of the first and second vacuum systems 222, 224, three-way valves may alternatively be used to selectively fluidly couple a given chamber with one of the first and second vacuum systems 222, 224.

The shared gas panel 204 may be coupled to each of the process chambers 110, 111 for providing one or more process gases to the first and second processing volumes 208, 214. For example, the shared gas panel may include one or more gases sources (not shown), for example where a gas from each gas source is metered out to each process chamber by one or more flow controllers, such as a mass flow controller, flow ratio controller or the like. Each gas source may be provided to each processing volume independently or to both processing volumes simultaneously, for example, to perform the same process in both process chambers 110, 111 simultaneously. As used herein, simultaneously means that the processes being performed in the two processing volumes at least partially overlap, begin after both substrates are delivered to the two processing volumes, and end prior to removal of either substrate from either of the two processing volumes.

A first three-way valve 226 can be disposed between the shared gas panel 204 and the first processing volume 208 of the process chamber 110 to provide a process gas from the shared gas panel 204 to the first processing volume 208. For example, the process gas may enter the process chamber 110 at a first showerhead 228 or any suitable gas inlet(s) used for providing a process gas to a process chamber. Further, the first three-way valve 226 may divert the process gas from the shared gas panel 204 (e.g., bypassing the first processing volume 208) into the second vacuum system 224 coupled to the second shared vacuum pump 206. In some embodiments, a measuring device 250 may optionally be coupled to the second vacuum system 224 through an access valve 249 to measure a desired processing parameter. For example, the measuring device 250 may be an independent mass flow system (IMFS) used to measure the flow of process gas into a given chamber. In such an embodiment, the three-way valve diverts the process gas to the second vacuum system 224, the valve coupling the given chamber is opened to fluidly couple the chamber with the second vacuum system 224, and the access valve 249 is opened to allow the IMFS to measure the flow of process gas into the chamber.

The first showerhead 228 may include an electrode having a first RF power source 229 coupled thereto, for example, for striking a plasma in the first processing volume 208 from a process gas. Alternatively, the first RF power source 229 may be coupled to an electrode separate from the first showerhead 228 (not shown) or coupled to one or more inductive coils (not shown) disposed outside the first processing volume 208.

A second three-way valve 232 can be disposed between the shared gas panel and second processing volume 214 of the second process chamber 111 to provide a process gas from the shared gas panel 204 to the second processing volume 21414. For example, the process gas may enter the second process chamber 111 at a second showerhead 234 or any suitable gas inlet(s) used for providing a process gas to a process chamber. Further, the second three-way valve 232 may divert the process gas from the shared gas panel 204 (e.g., bypassing the second processing volume 214) into the second vacuum system 224 coupled to the second shared vacuum pump 206.

The second showerhead 234 may include an electrode having a second RF power source 235 coupled thereto, for example, for striking a plasma in the second processing volume 214 from a process gas. Alternatively, the second RF power source 235 may be coupled to an electrode separate from the second showerhead 234 (not shown) or coupled to one or more inductive coils (not shown) disposed outside the second processing volume 214.

The first and second three-way valves 226, 232 may operate in response to a process endpoint detected, for example, by a first endpoint detector 236 for detecting the process endpoint in the process chamber 110 and by a second endpoint detector 238 for detecting the process endpoint in the second process chamber 111. For example, a controller, for example such as the system controller 144 or an individual controller (not shown) coupled to one or more of the components of the twin chamber processing system 101, may be configured to receive a first signal from the first endpoint detector 236 when the process endpoint is reached in the process chamber 110 and to instruct the first three-way valve 226 to divert a process gas into the second vacuum system 224 if the process endpoint has not been reached in a process running in the second process chamber 111. For example, although a process may be synchronized in each process chamber 110, 111 initially, the process may end at different times in each process chamber 110, 111 due to, for example, small variations in a substrate being processed, substrate temperature, plasma density or flux, or the like in each process chamber 110, 111. Similarly, the controller may be configured to receive a second signal form the second endpoint detector 238 when the process endpoint is reached in the second process chamber 111 and to instruct the second three-way valve 232 to divert a process gas into the second vacuum system 224 if the process endpoint has not been reached in a process running in the process chamber 110.

Alternatively, and for example, the controller may, upon receiving the first signal from the first endpoint detector 236 that a process endpoint has been reached for a process being performed on a substrate in process chamber 110, turn off power to the first RF power source 229 to terminate a plasma in the first processing volume 208. Further, the process gas may continue to flow into the first processing volume 208 after the first RF power source 229 is turned off instead of being diverted by the first three-way valve 226 when the process endpoint is reached. A similar alternative embodiment upon receiving the second signal from the second endpoint detector 238 may be performed in the second process chamber 111. Further, if a signal is received from either of the first or second endpoint detectors 236, 238, the controller may, in some embodiments, terminate the processes in both chambers regardless of whether the process endpoint is detected in both chambers. For example, if the first signal is received from the first endpoint detector 236 that a process endpoint has been reached in the process chamber 110, the controller may terminate the processes in both process chambers 110, 111 even though the second signal has not been received from the second endpoint detector 238. Alternatively, if the first signal is received signaling a process endpoint has been reached in the process chamber 110, the controller may not take any action in either process chamber 110, 111 until the second signal is received signaling a process endpoint has been reached in the process chamber 111 as well.

Alternatively, a process need not be precisely synchronized in both process chambers 110, 111 and for example may begin in each chamber when a substrate has reached the appropriate process temperature or another similar process condition. Accordingly, when a process endpoint is reach in a given chamber, the process gas is diverted by a three-way valve into the second vacuum system 224 until the process endpoint is reached in the adjacent chamber prior to removing the substrates from the process chambers 110, 111 or prior to beginning a further processing step.

The shared gas panel may further provide a gas for purging the process chambers 110, 111. For example, a vent line 240 may be selectively coupled to each of the first and second processing volumes 208, 214 directly (as shown). For example, the purge gas may include nitrogen (N₂), argon (Ar), helium (He), or the like. The purge gas may be selectively provided to the first processing volume 208 via a first purge valve 242 disposed between the shared gas panel 204 and the first processing volume 208. Similarly, the purge gas may be selectively provided to the second processing volume 214 via a second purge valve 244 disposed between the shared gas panel 204 and the second processing volume 214. Further, in applications where the purge gas is utilized to vent each process chamber 110, 111 to atmosphere, a vent (not shown), for example such as a valve or the like, may be provided for each process chamber 110, 111 such that each process chamber 110, 111 may be vented to atmosphere independently from the other chamber.

Returning to FIG. 1, the system controller 144 is coupled to the processing system 100. The system controller 144 controls the operation of the processing system 100 using a direct control of the process chambers 110, 111, 112, 132, 128, 120 of the processing system 100 or alternatively, by controlling individual controllers (not shown) associated with the process chambers 110, 111, 112, 132, 128, 120 and/or each twin chamber processing system 101, 103, 105 and the processing system 100. In operation, the system controller 144 enables data collection and feedback from the respective chambers and system controller 144 to optimize performance of the processing system 100.

The system controller 144 generally includes a central processing unit (CPU) 138, a memory 140, and support circuit 142. The CPU 138 may be one of any form of a general purpose computer processor that can be used in an industrial setting. The support circuits 142 are conventionally coupled to the CPU 138 and may comprise cache, clock circuits, input/output subsystems, power supplies, and the like. The software routine, such as a method 300 described below for controlling one or more chamber processes, such as reducing pressure, venting or purging each chamber of a twin chamber processing system, when executed by the CPU 138, transform the CPU 138 into a specific purpose computer (controller) 144. The software routines may also be stored and/or executed by a second controller (not shown) that is located remotely from the processing system 100.

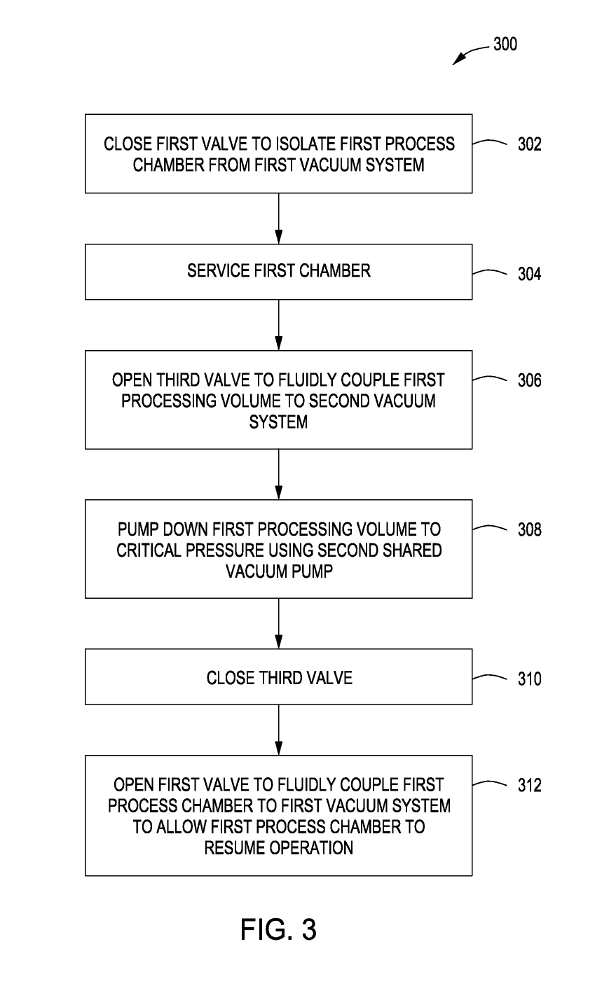

FIG. 3 depicts a flow chart for a method 300 for selectively coupling one of the process chambers of a multi-chamber processing system to one of a first and second vacuum system is depicted in FIG. 3, and described below with respect to the twin chamber processing system 101 depicted in FIG. 2. For example, because the first and second processing volumes 208, 214 share common vacuum systems, e.g., the first and second vacuum systems 222, 224, each processing volume may be selectively fluidly coupled to an independent one of the first and second vacuum systems 222,224 to prevent backflow into the other processing volume if the other processing volume is at a lower pressure. The method 300 will be explained with respect to the first process chamber 110. However, the method 300 is identical with respect to the second process chamber 111 when the second process chamber 111 needs to be serviced. The method 300 begins with the first and second valves 218,220 in the open position and the third and fourth valves 210,216 in the closed position so that both chambers are fluidly coupled to the first shared vacuum pump 202 during processing.

At 302 (i.e., when the first process chamber 110 is determined to need servicing), the first valve 218 is closed, thus isolating the first process chamber 110 from the first vacuum system 222. At 304, servicing of the chamber is performed. Servicing may include, for example, preventative maintenance, repairs, etc. After servicing of the first process chamber 110 is completed, at 306, the third valve 210 is opened to fluidly couple the first processing volume 208 to the second vacuum system 224, which is coupled to the second shared vacuum pump 206. At 308, the second shared vacuum pump 206 pumps down the first processing volume 208 to a crossover pressure (e.g., less than about 200 mTorr) less than or equal to an operating pressure of the first shared vacuum pump. Once the pressure in the first processing volume 208 is at the crossover pressure, at 310 the third valve 210 is closed. Finally, at 312, the first valve 218 is opened to once again fluidly couple the first process chamber 110 to the first vacuum system 222 and allow the first process chamber to continue operation.

Thus, methods and apparatus for a multi-chamber processing system having shared vacuum systems have been provided. The inventive multi-chamber processing system advantageously allows a first chamber to be serviced while allowing the remaining chambers to operate normally. Additionally, the inventive multi-chamber processing system advantageously prevents contamination of the remaining process chamber after the first process chamber has been serviced.

While the foregoing is directed to embodiments of the present disclosure, other and further embodiments of the disclosure may be devised without departing from the basic scope thereof.

1. A multi-chamber processing system for processing substrates, comprising:
a first process chamber having a first process volume;
a second process chamber having a second process volume;
a first vacuum system coupled to the first and second process chambers through first and second valves and to a first shared vacuum pump; and
a second vacuum system coupled to the first and second process chambers through third and fourth valves and to a second shared vacuum pump, wherein the second vacuum system is fluidly independent from the first vacuum system.

2. The multi-chamber processing system of claim 1, wherein the first shared vacuum pump is a roughing pump and the second shared vacuum pump is a turbomolecular pump.

3. The multi-chamber processing system of claim 1, further comprising:
a measuring device coupled to the second vacuum system through an access valve, wherein the measuring device is configured to measure a processing parameter of the first and second process chambers.

4. The multi-chamber processing system of claim 3, further comprising:
a shared gas panel coupled to the first and second process chambers and configured to provide one or more process gases to the first and second processing volumes, wherein the processing parameter is a flow of the one or more process gases into one of the first and second processing volumes.

5. The multi-chamber processing system of claim 4, further comprising:
a first three-way valve disposed between the shared gas panel and the first processing volume to selectively provide the one or more process gases from the shared gas panel to one of the first processing volume or the measuring device; and
a second three-way valve disposed between the shared gas panel and the second processing volume to selectively provide the one or more process gases from the shared gas panel to one of the second processing volume or the measuring device.

6. The multi-chamber processing system of claim 4, wherein the first process chamber includes a first showerhead fluidly coupled to the shared gas panel, and wherein the second process chamber includes a second showerhead fluidly coupled to the shared gas panel.

7. The multi-chamber processing system of claim 6, wherein first showerhead is coupled to a first RF power source, and wherein second showerhead is coupled to a second RF power source.

8. The multi-chamber processing system of claim 1, wherein the first process chamber includes a first endpoint detector configured to detect a process endpoint in the first process chamber, and wherein the second process chamber includes a second endpoint detector configured to detect a process endpoint in the second process chamber.

9. A method of selectively coupling a chamber of a multi-chamber processing system to one of a first vacuum system or a second vacuum system, comprising:
closing a first valve coupling the chamber to the first vacuum system to isolate the chamber from the first vacuum system;
performing servicing of the chamber;
opening a third valve coupling the chamber to the second vacuum system;
pumping down the chamber to a crossover pressure using a second shared vacuum pump coupled to the second vacuum system;
closing the third valve to isolate the chamber from the second vacuum system; and
opening the first valve to fluidly couple the chamber to the first vacuum system to allow the chamber to resume operation,
wherein the first and second vacuum systems are fluidly independent of each other and are coupled to all chambers of the multi-chamber processing system.

10. The method of claim 9, wherein a first shared vacuum pump is coupled to the first vacuum system, wherein a second shared vacuum pump is coupled to the second vacuum system.

11. The method of claim 10, wherein the first shared vacuum pump is a roughing pump and the second shared vacuum pump is a turbomolecular pump.

12. The method of claim 10, wherein the crossover pressure is less than about 200 mTorr.

13. A multi-chamber processing system for processing substrates, comprising:
a first process chamber having a first process volume;
a second process chamber having a second process volume;
a first vacuum system coupled to the first and second process chambers through first and second valves and to a roughing pump; and
a second vacuum system coupled to the first and second process chambers through third and fourth valves and to a turbomolecular pump, wherein the second vacuum system is fluidly independent from the first vacuum system,
wherein the roughing pump is configured to maintain a processing pressure in all chambers of the multi-chamber processing system, and
wherein the turbomolecular pump is configured to reduce a pressure in one of the first and second processing volumes being serviced below a crossover pressure less than the processing pressure provided by the roughing pump.

14. The multi-chamber processing system of claim 13, further comprising:
a measuring device coupled to the second vacuum system through an access valve, wherein the measuring device is configured to measure a processing parameter of the first and second process chambers.

15. The multi-chamber processing system of claim 14, further comprising:
a shared gas panel coupled to the first and second process chambers and configured to provide one or more process gases to the first and second processing volumes, wherein the processing parameter is a flow of the one or more process gases into one of the first and second processing volumes.

16. The multi-chamber processing system of claim 15, further comprising:
a first three-way valve disposed between the shared gas panel and the first processing volume to selectively provide the one or more process gases from the shared gas panel to one of the first processing volume or the measuring device; and
a second three-way valve disposed between the shared gas panel and the second processing volume to selectively provide the one or more process gases from the shared gas panel to one of the second processing volume or the measuring device.

17. The multi-chamber processing system of claim 15, wherein the first process chamber includes a first showerhead fluidly coupled to the shared gas panel, and wherein the second process chamber includes a second showerhead fluidly coupled to the shared gas panel.

18. The multi-chamber processing system of claim 17, wherein first showerhead is coupled to a first RF power source, and wherein second showerhead is coupled to a second RF power source.

19. The multi-chamber processing system of claim 13, wherein the first process chamber includes a first endpoint detector configured to detect a process endpoint in the first process chamber, and wherein the second process chamber includes a second endpoint detector configured to detect a process endpoint in the second process chamber.

20. The multi-chamber processing system of claim 13, wherein the crossover pressure is less than about 200 mTorr.
